(19) United States
(12) Patent Application Publication
(10) Pub. No.: US 2025/0280669 A1
(43) Pub. Date: Sep. 4, 2025

(54) DISPLAY APPARATUS

(71) Applicant: LG Display Co., Ltd., Seoul (KR)

(72) Inventors: Heonkwang PARK, Paju-si (KR); Minseo KIM, Paju-si (KR)

(73) Assignee: LG Display Co., Ltd., Seoul (KR)

(21) Appl. No.: 19/047,336

(22) Filed: Feb. 6, 2025

(30) Foreign Application Priority Data
Feb. 29, 2024 (KR) 10-2024-0029806

(51) Int. Cl. H10K 59/124; H10K 59/121; H10K 59/122; H10K 59/131; H10K 59/80

(52) U.S. Cl. CPC H10K 59/124; H10K 59/1213; H10K 59/122; H10K 59/131; H10K 59/873

(57) ABSTRACT

A display apparatus can include a substrate having a display area and a non-display area adjacent to the display area, a plurality of pixels and a first area that are disposed in the display area, a first planarization layer disposed on a plurality of transistors included in one of the pixels, and a connection electrode and a second planarization layer disposed on the first planarization layer. The first area includes a hole area, a first pattern part, a first dam part, a plurality of insulating layer, and a cover layer. The end portions of the plurality of insulating layers are disposed between the hole area and the first pattern part. The cover layer covers the end portions of the plurality of insulating layers.

### CROSS-REFERENCE TO RELATED APPLICATION

The present application claims priority to Korean Patent Application No. 10-2024-0029806, filed in the Republic of Korea on Feb. 29, 2024, the entire contents of which is hereby expressly incorporated by reference into the present application.

### BACKGROUND

### Technical Field

The present disclosure relates to a display apparatus, and in particular, to a display apparatus that is capable of blocking external moisture and preventing camera hole cracks in a display apparatus in which a camera hole area is disposed in a display area.

### Discussion of the Related Art

Modern display apparatuses that can display various pieces of information and interact with users viewing the corresponding information need to have various sizes, shapes, and functions.

Examples of the display apparatus include a liquid crystal display apparatus (LCD), a field emission display apparatus (FED), an organic light emitting diode (OLED) display apparatus, etc.

The OLED display apparatus is self-luminous display apparatuses and unlike the LCD, do not require a separate light source. Thus lightweight and thin OLED display apparatuses can be manufactured. In addition, the OLED display apparatus is advantageous in terms of power consumption due to a low-voltage operation and also has excellent color expression, response speed, viewing angle, and contrast ratio (CR), and thus is researched as a next-generation display.

The OLED display apparatus uses a plurality of thin film transistors (or “TFT”) to control a current flowing in an organic light emitting diode to display an image.

The display apparatus is being developed by adding a camera, a speaker, and a sensor.

In particular, a hole in display structure that forms a hole in a device so that a sensor such as a camera can be disposed in a display area to maximize the display area of the display apparatus is being applied.

Since the hole is formed in the display apparatus, there can be limitations that external moisture can penetrate the display area inside a display panel and cracks can occur in layers near the hole in a process of forming the hole.

### SUMMARY OF THE DISCLOSURE

In the present disclosure, a through hole can be formed in an area in which a camera is disposed in a display area of a display apparatus.

The through hole can be formed by removing a substrate and layers on the substrate.

To form the through hole in the display area, a first area including a hole area, a first pattern part, a first dam part, and a second pattern part can be disposed.

In the first pattern part adjacent to the hole area of the first area, a plurality of first patterns including a pillar-shaped lower pattern and a trapezoid-shaped upper pattern on the lower pattern can be disposed to disconnect a light emitting layer.

To form the through hole, a laser trimming process can be performed to cut the substrate and the plurality of layers using a laser.

In the hole area formed by removing the substrate and the layers on the substrate, side surfaces of the layers on the substrate can be exposed to the outside.

There can be a limitation that external moisture flowing into an organic insulating layer made of an organic material among layers on the substrate exposed to the outside spreads through layers adjacent to the hole area to penetrate the display area, which can deteriorate the quality of the display apparatus.

In addition, there can be a problem that cracks can occur in the layers near the hole area due to the laser trimming process and propagate.

Therefore, in aspects of the present disclosure, a display apparatus capable of preventing or minimizing crack propagation by arranging a cover layer that prevents or minimizes crack propagation in a trimming margin part of a first area formed to arrange a camera of the hole in display was invented.

In addition, in aspects of the present disclosure, a display apparatus capable of preventing or minimizing a moisture penetration path by improving a structure of a first pattern part adjacent to a hole area was also invented.

Embodiments of the present disclosure are directed to providing a display apparatus that is capable of preventing or minimizing crack propagation and moisture penetration into a first area formed to arrange a camera.

The objects of embodiments of the present disclosure are not limited to the above-described objects, and other objects that are not described will be able to be clearly understood by those skilled in the art from the following description.

A display apparatus according to an embodiment of the present disclosure can include a substrate including a display area and a non-display area surrounding the display area, a plurality of pixels and a first area that are disposed in the display area, each of the plurality of pixels including a plurality of transistors, a first planarization layer disposed on the plurality of transistors, and a connection electrode and a second planarization layer on the first planarization layer, wherein the first area can include a hole area, a first pattern part, and a first dam part, end portions of a plurality of insulating layers disposed between the hole area and the first pattern part, and a cover layer covering the end portions of the plurality of insulating layers.

A display apparatus according to an embodiment of the present disclosure includes a substrate including a display area, a plurality of insulating layers on the substrate, a first area disposed in the display area and including a hole area, a trimming margin part, and a pattern part, and a cover layer covering side surfaces of the plurality of insulating layers exposed along the trimming margin part.

Detailed matters of other embodiments are included in a detailed description and accompanying drawings.

According to the display apparatus according to the embodiments of the present disclosure, by improving the structure formed to arrange the camera in the display area, it is possible to effectively prevent or minimize the external moisture penetration into the panel and improve the quality deterioration of the panel due to the moisture penetration.

According to the display apparatus according to the embodiments of the present disclosure, it is possible to prevent or minimize cracks that can occur due to the formation of the through hole in the first area formed to arrange the camera in the display area from propagating therein.

The effects of the present disclosure are not limited to the above-described effects, and other effects that are not described will be able to be clearly understood by those skilled in the art from the following description.

Since the contents of the invention described in the above-described problems to be solved, means to solve the problems, and effects do not specify the essential features of the claims, the scope of the claims is not limited by the items described in the contents of the disclosure.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view showing a display apparatus according to one or more embodiments of the present disclosure.

FIG. 2 is an enlarged plan view showing a portion of a first area PH of area P in FIG. 1.

FIG. 3 is a cross-sectional view showing one example of a cross-section along line A-A′ in FIG. 1.

FIG. 4 shows a cross-sectional view cut along line B-B′ in FIG. 2 according to one embodiment of the present disclosure.

FIG. 5 shows a cross-sectional view cut along line B-B′ in FIG. 2 according to another embodiment of the present disclosure.

FIG. 6 shows a cross-sectional view cut along line B-B′ in FIG. 2 according to another embodiment of the present disclosure.

FIG. 7 shows a cross-sectional view cut along line B-B′ in FIG. 2 according to another embodiment of the present disclosure.

### DETAILED DESCRIPTION OF THE EMBODIMENTS

Advantages and features of the present disclosure and methods for achieving them will become clear with reference to embodiments described below in detail in conjunction with the accompanying drawings. However, the present disclosure is not limited to the embodiments disclosed below but can be implemented in various different forms, these embodiments are merely provided to make the disclosure of the present disclosure complete and fully inform those skilled in the art to which the present disclosure pertains of the scope of the present disclosure.

Since shapes, sizes, ratios, angles, numbers, and the like disclosed in the drawings for describing the embodiments of the present disclosure are illustrative, the present disclosure is not limited to the illustrated items. The same reference number denotes the same components throughout the disclosure. In addition, in describing the present disclosure, when it is determined that the detailed description of a related known technology can unnecessarily obscure the gist of the present disclosure, detailed description thereof will be omitted. When “comprise,” “have,” “consist of,” etc. described herein are used, other parts can be added unless “only” is used. When a component is expressed in the singular, it includes a case in which the component is provided as a plurality of components unless specifically stated otherwise. Further, the term “can” fully encompasses all the meanings and coverages of the term “may.”

In construing a component, the component is construed as including the margin of error even when there is no separate explicit description about the margin of error.

When the positional relationship is described, for example, when the positional relationship between two parts is described using “on,” “above,” “under,” “next to,” or the like, one or more other parts can be located between the two parts unless “immediately” or “directly” is used.

When the temporal relationship is described, when the temporal relationship is described using “after,” “subsequently,” “then,” “before,” etc., it can also include a non-consecutive case unless “immediately” or “directly” is used.

Although terms such as first and second are used to describe various components, these components are not limited by these terms. These terms are only used to distinguish one component from another component. Therefore, a first component described below can be a second component within the technical spirit of the present disclosure.

In the description of the components of the present disclosure, terms such as first, second, A, B, (a), and (b) can be used. These terms are only for the purpose of distinguishing one component from another component, and the nature, sequence, order, or the like of the corresponding component is not limited by these terms. When a certain component is described as being “connected,” “coupled,” or “joined” to another component, the certain component can be connected or joined directly to another component, but it should be understood that other components can be “interposed” between the certain component and another component, which can be connected or coupled indirectly unless otherwise stated specially.

It should be understood that “at least one” includes any combination of one or more of associated components. For example, “at least one of first, second, and third components” can include not only the first, second, or third component, but also any combination of two or more of the first, second, and third components.

In the present disclosure, “device” can include a display apparatus, such as a liquid crystal module (LCM) and an organic light emitting display module (OLED module), including a display panel and a driver for driving the display panel. In addition, the apparatus can also include a set electronic apparatus or a set device (or a set apparatus), such as a laptop computer, a television, a computer monitor, a vehicle or automotive apparatus, a mobile electronic apparatus of a smartphone, an electronic pad, etc., which is a complete product or final product including an LCM, an OLED, etc.

Therefore, the apparatus in the present disclosure can include a display apparatus such as an LCM or OLED module and a set apparatus that is an application product or end-consumer apparatus including an LCM or OLED module, etc.

In addition, in some embodiments, an LCM, OLED module that is composed of a display panel, a driving unit, etc. can be referred to as a “display apparatus,” and an electronic apparatus as a finished product including an LCM or OLED module can be separately referred to as a “set apparatus.” For example, a display apparatus can include a display panel of an LCD or an OLED, and a source printed circuit board (PCB) as a control unit for driving the display panel. The set apparatus can further include a set PCB as a set control unit electrically connected to the source PCB to drive the entirety of the set device.

The display panel used in the embodiments of the present disclosure can be any type of display panel, such as an OLED display panel or an electroluminescent display panel. However, embodiments are not limited thereto. For example, the display panel can be a display panel that can generate sound by being vibrated by a vibration device according to an embodiment of the present disclosure. The display panel applied to the display apparatus according to embodiments of the present disclosure is not limited to the shape or size of the display panel.

Features of various embodiments of the present disclosure can be coupled or combined partially or entirely, and various technological interworking and driving are possible, and the embodiments can be implemented independently of each other or implemented together in an associated relationship.

Scales of components shown in the drawings differ from the actual scale for convenience of description, and thus are not limited to the scales shown in the drawings.

Hereinafter, various embodiments of the present disclosure will be described in detail with reference to the accompanying drawings. All the components of each display apparatus according to all embodiments of the present disclosure are operatively coupled and configured.

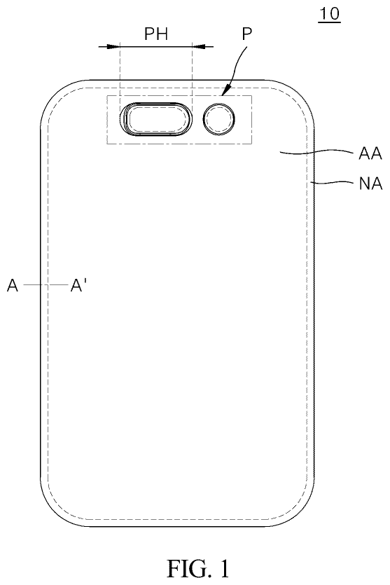

FIG. 1 is a schematic plan view showing one example of a display apparatus according to one or more embodiments of the present disclosure.

Referring to FIG. 1, a display apparatus 10 can include a plurality of areas. For example, the display apparatus 10 includes one or more display areas AA (or active areas) that are areas in which a picture image is displayed, and a pixel array PXL is formed inside the display area AA. One or more non-display areas NA (or non-active areas) in which the picture image is not displayed can include a driving circuit part and a dam part and can be provided on one side surface of the display area AA. For example, the non-display area NA can be adjacent to one or more side surfaces of the display area AA.

The non-display area NA can surround the substantially rectangular display area AA and can be positioned outside the display area AA. As an example, the non-display area NA can surround the display area AA entirely or only in part(s). However, it should be understood that shapes of the display area AA and the arrangement of the non-display area NA adjacent to the display area AA are not specifically limited to the exemplary display apparatus 10 shown in FIG. 1. The display area AA and the non-display area NA can have any shape of the display apparatus 10. Examples of these shapes can include a pentagon, hexagon, circle, oval, etc., and the embodiments of the present disclosure are not limited thereto.

Each pixel PXL of the display area AA can include sub-pixels, and the sub-pixel can display colors of red (R), green (G), blue (B), and white (W). In addition, each of the pixel PXL and the sub-pixel can be associated with a pixel circuit including one or more transistors (thin film transistors (TFTs)) manufactured on a substrate of the display apparatus 10. Each pixel circuit can be electrically connected to a gate line and a data line to communicate with one or more driving circuits, for example, a gate driver (GIP) and a data driver (D-IC) that are positioned in the non-display area NA of the display apparatus 10.

The one or more driving circuits can be implemented using thin film transistors (TFTs) formed in the non-display area NA. For example, the gate driver (GIP) can be implemented using a plurality of TFTs on the substrate of the display apparatus 10. Non-limiting examples of circuits that can be implemented as TFTs on the substrate can include an inverter circuit, a multiplexer, and an electro static discharge (ESD) circuit, and the embodiments of the present disclosure are not limited thereto.

Some driving circuits can be provided as integrated circuit (IC) chips and mounted in the non-display area NA of the display apparatus 10 using chip-on-glass (COG) or other similar methods. In addition, some driving circuits can be mounted on another substrate and coupled to connection interfaces (pads/bumps, pins) disposed in the non-display area NA using a printed circuit such as a flexible printed circuit board (PCB), a chip-on-film (COF), a tape-carrier-package (TCP), or other suitable technologies.

In the embodiments of the present disclosure, at least two different types of TFTs are used in a TFT substrate for display. The types of TFTs employed in some pixel circuits and some driving circuits can vary depending on the requirements of the display.

For example, the pixel circuit can be implemented using a TFT having an oxide active layer (oxide TFT), and the driving circuit can be implemented using a TFT having a low-temperature polycrystalline silicon active layer (LTPS TFT) and a TFT having an oxide active layer. Unlike LTPS TFTs, oxide TFTs do not undergo a threshold voltage (Vth) fluctuation problem from pixel-to-pixel. A uniform threshold voltage (Vth) can be acquired in an array of pixel circuits for display. The problem of uniformity of threshold voltage (Vth) between TFTs implementing the driving circuit will have less direct influence on the uniformity of luminance of pixels.

The driving circuits (e.g., GIP) can have gate drive ICs embedded inside the display panel to reduce the cost due to a reduction in the number of drive ICs and provide high-speed scan signals to the display area of the display panel.

Using the driving circuits on the substrate implemented using LTPS TFTs, signals and pieces of data can be provided to pixels using a higher clock than a case in which all TFTs in the TFT panel are formed as oxide TFTs. Therefore, a display capable of a high-speed operation can be provided without spots such as Mura. For example, the advantages of oxide TFT and LTPS TFT can be combined with the design of the TFT panel, and oxide TFT and LTPS TFT can be used by being selected according to each advantage.

The display area AA can include a first area PH. The first area PH can include a hole area H to arrange a camera in the display area AA.

At least one first area PH can be disposed in the display area AA and can include a circular or oval hole area H.

In the first area PH, sensors such as a camera, a distance detection sensor, and a face recognition sensor can be disposed.

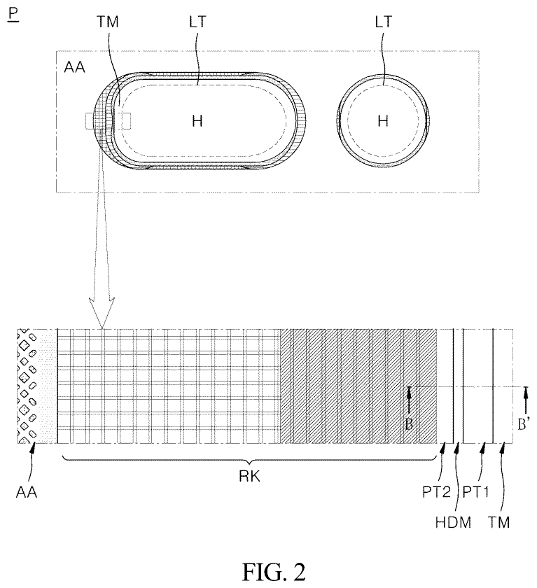

FIG. 2 is an enlarged plan view showing a portion of the first area PH in FIG. 1.

Referring to FIG. 2, to arrange a camera in the display area AA, the first area PH includes the hole area H, a trimming margin part TM surrounding the hole area H, a first pattern part PT1, a hole dam part HDM, a second pattern part PT2, and a routing line area RK.

A substrate 100 of the display apparatus 10 and electrodes and insulating layers on the substrate 100 can be removed along a laser trimming line LT.

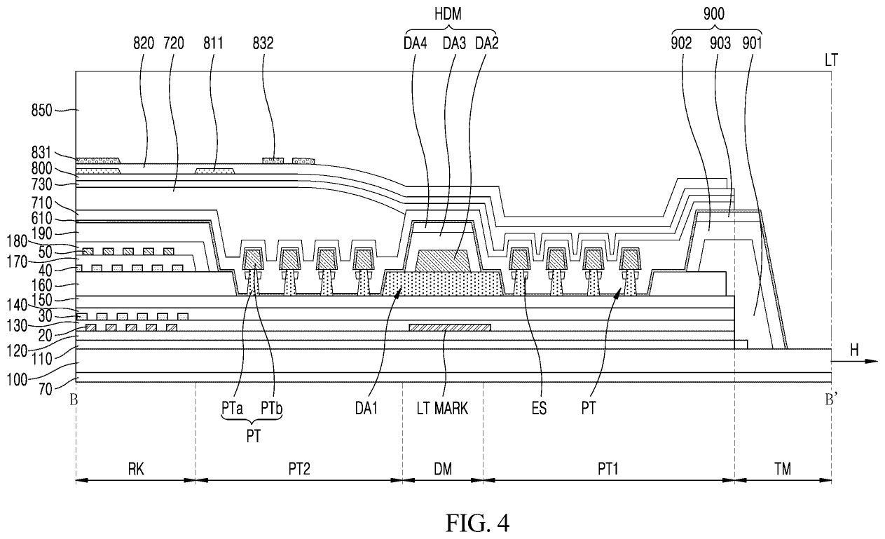

The first area PH will be described later in detail with reference to FIGS. 4 to 7.

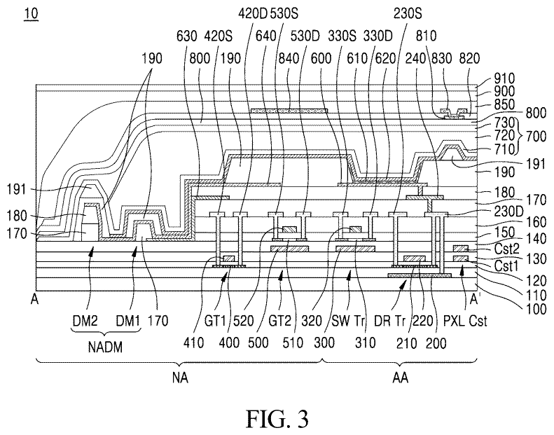

FIG. 3 is a schematic cross-sectional view showing one example of a cross-section along line A-A′ in FIG. 1.

Referring to FIG. 3, the substrate 100 of the display apparatus according to the embodiment of the present disclosure can include a first substrate, a second substrate, and an intermediate layer between the first substrate and the second substrate.

The first substrate and the second substrate can be made of at least one of polyimide, polyethersulfone, polyethylene terephthalate, and polycarbonate, and the embodiments of the present disclosure are not limited thereto. When the substrate is made of a plastic material, the manufacturing process of the display apparatus can be performed in a state in which a support substrate made of glass is disposed under the substrate, and the support substrate can be released after the manufacturing process of the display apparatus is completed. In addition, after the support substrate is released, a back plate (or plate) for supporting the substrate can be disposed under the substrate. When the substrate is made of a plastic material, moisture can penetrate the substrate and then the thin film transistor or a light emitting element layer, thereby deteriorating the performance of the display apparatus.

The display apparatus according to the embodiment of the present disclosure can be composed of two substrates of the first substrate and the second substrate that are made of a plastic material to prevent a deterioration in performance of the display apparatus due to moisture penetration. In addition, by forming an intermediate layer, which is an inorganic film, between the first substrate and the second substrate, it is possible to block moisture from penetrating the substrate, thereby improving the performance reliability of products. The intermediate layer can be made of an inorganic film. For example, the intermediate layer can be formed of a single layer or multiple layers of silicon nitride (SiNₓ) or silicon oxide (SiOₓ), but is not limited thereto.

The display apparatus formed on the substrate 100 can include a plurality of areas. In the present disclosure, the display apparatus is composed of the display area AA and the non-display area NA, but is not limited thereto.

A buffer layer formed of a single layer or multiple layers of silicon nitride (SiNₓ) or silicon oxide (SiOₓ) can be disposed on one surfaces of the display area AA and the non-display area NA on the substrate 100. The buffer layer can increase adhesive strength between layers formed on the buffer layer and the substrate 100 and serve to block any type of defect factor, such as an alkaline component leaking from the substrate 100. In addition, the buffer layer can delay the spread of moisture or oxygen penetrating the substrate 100.

The buffer layer can be omitted based on the type and material of the substrate, the structure and type of the thin film transistor, etc.

Transistors of the display area AA and the non-display area NA can be formed on the substrate 100 and the buffer layer. The transistors of the display area AA can include a switching transistor SW Tr and a driving transistor DR Tr for driving a sub-pixel, and the transistors of the non-display area NA can include a first gate driving transistor GT1 and a second gate driving transistor GT2 for driving the gate driver (GIP).

A light shielding layer 200 can be disposed on the substrate 100 or the buffer layer to overlap at least a portion of the driving transistor DR Tr.

The light shielding layer 200 can shield light directed to a first semiconductor layer 210 of the driving transistor DR Tr and connected to a first drain electrode 230D, thereby preventing a phenomenon in which parasitic carriers accumulate in the first semiconductor layer 210 to quickly increase a drain current or a change in threshold voltage due to such a phenomenon.

The light shielding layer 200 can be formed of a single layer or multiple layers having at least one of titanium (Ti), molybdenum (Mo), copper (Cu), aluminum (Al), silver (Ag), chromium (Cr), gold (Au), neodymium (Nd), and nickel (Ni), and the embodiments of the present disclosure are not limited thereto.

A first insulating layer 110 can be disposed on the light shielding layer 200.

The first insulating layer 110 can be made of an insulating material such as silicon nitride (SiNₓ) or silicon oxide (SiOₓ) and can also be made of an insulating inorganic material or organic material, and the embodiments of the present disclosure are not limited thereto.

The first semiconductor layer 210 of the driving transistor DR Tr of the display area AA and a second semiconductor layer 400 of the first gate driving transistor GT1 of the non-display area NA can be disposed on the first insulating layer 110, and the first semiconductor layer 210 can overlap the light shielding layer 200.

The first semiconductor layer 210 and the second semiconductor layer 400 can be made of low temperature polycrystalline silicon (LTPS).

The first gate insulating layer 120 can be disposed on the first semiconductor layer 210 and the second semiconductor layer 400. The first gate insulating layer 120 can be made of an insulating material such as silicon nitride (SiNₓ) or silicon oxide (SiOₓ) and can also be made of an insulating inorganic material or organic material, and the embodiments of the present disclosure are not limited thereto.

A first gate electrode 220 and a second gate electrode 410 can be disposed on the first gate insulating layer 120 to overlap the first semiconductor layer 210 and the second semiconductor layer 400, and the first gate electrode 220 and the second gate electrode 410 can be made of one or more materials of silver (Ag), molybdenum (Mo), copper (Cu), titanium (Ti), aluminum (Al), chromium (Cr), nickel (Ni), neodymium (Nd), tungsten (W), and gold (Au), and the embodiments of the present disclosure are not limited thereto.

A first capacitor electrode Cst1 of a capacitor PXL Cst included in a sub-pixel can be formed in the same process as the first gate electrode 220 and the second gate electrode 410.

A second insulating layer 130 can be disposed on the first gate electrode 220, the second gate electrode 410, and the first capacitor electrode Cst1.

The second insulating layer 130 can be made of an insulating material such as silicon nitride (SiNₓ) or silicon oxide (SiOₓ) and can also be made of an insulating inorganic material or organic material, and the embodiments of the present disclosure are not limited thereto.

A second capacitor electrode Cst2 of the sub-pixel capacitor PXL Cst can be disposed on the second insulating layer 130. The second capacitor electrode Cst2 can be disposed to overlap the first capacitor electrode Cst1 and made of the same material as the first capacitor electrode Cst1.

A first metal layer 300 overlapping the switching transistor SW Tr of the sub-pixel and a second metal layer 500 overlapping the second gate driving transistor GT2 can be disposed by being formed on the second insulating layer 130.

The first metal layer 300 and the second metal layer 500 can be driven by lower gate electrodes of the switching transistor SW Tr and the second gate driving transistor GT2, respectively, or used as light shielding layers that shield light reflected to a third semiconductor layer 310 and a fourth semiconductor layer 510 of the switching transistor SW Tr and the second gate driving transistor GT2, and the embodiments of the present disclosure are not limited thereto.

A third insulating layer 140 can be disposed on the second capacitor electrode Cst2, the first metal layer 300, and the second metal layer 500.

The third insulating layer 140 can be made of an insulating material such as silicon nitride (SiNₓ) or silicon oxide (SiOₓ) and can also be made of an insulating organic material, etc., and the embodiments of the present disclosure are not limited thereto.

The third semiconductor layer 310 of the switching transistor SW Tr of the display area AA and the fourth semiconductor layer 510 of the second gate driving transistor GT2 of the non-display area NA can be disposed on the third insulating layer 140.

The third semiconductor layer 310 and the fourth semiconductor layer 510 can be made of a metal oxide semiconductor, for example, one of IGZO, IZO, IGTO, and IGO, but are not limited thereto.

The metal oxide semiconductor can have improved conductive properties by a doping process that injects impurities and include a channel area in which a channel through which electrons or holes move is formed, and a source area and a drain area that are conductive areas at both sides of the channel area. A source electrode and a drain electrode can be connected to the source area and the drain area.

The second gate insulating layer 150 can be disposed on the third semiconductor layer 310 and the fourth semiconductor layer 510. The second gate insulating layer 150 can be disposed between the third semiconductor layer 310 and the fourth semiconductor layer 510 and the third gate electrode 320 and the fourth gate electrode 520 to insulate the third semiconductor layer 310 and the fourth semiconductor layer 510, and the third gate electrode 320 and the fourth gate electrode 520.

The second gate insulating layer 150 can be made of an insulating inorganic material such as silicon nitride (SiNₓ) or silicon oxide (SiOₓ) and can also be made of an insulating organic material, but is not limited thereto.

The third gate electrode 320 and the fourth gate electrode 520 can be disposed on the second gate insulating layer 150 to overlap the third semiconductor layer 310 and the fourth semiconductor layer 510.

The third gate electrode 320 and the fourth gate electrode 520 can be formed of a single layer or multiple layers made of one of silver (Ag), molybdenum (Mo), copper (Cu), titanium (Ti), aluminum (Al), chromium (Cr), nickel (Ni), neodymium (Nd), tungsten (W), and gold (Au), or an alloy thereof, but is not limited thereto.

A fourth gate insulating layer 160 can be disposed on the third gate electrode 320 and the fourth gate electrode 520.

The fourth insulating layer 160 can be made of an insulating inorganic material such as silicon nitride (SiNₓ) and silicon oxide (SiOₓ) or made of one or more of organic insulating materials such as benzocyclobutene (BCB), an acrylic resin, an epoxy resin, a phenolic resin, a polyamide resin, or a polyimide resin, and the embodiments of the present disclosure are not limited thereto.

On the fourth insulating layer 160, a first source electrode 230S and a first drain electrode 230D that are connected to the first semiconductor layer 210, a second source electrode 420S and a second drain electrode 420D that are connected to the second semiconductor layer 400, a third source electrode 330S and a third drain electrode 330D that are connected to the third semiconductor layer 310, and a fourth source electrode 530S and a fourth drain electrode 530D that are connected to the fourth semiconductor layer 510 can be disposed.

The first source electrode 230S, the first drain electrode 230D, the second source electrode 420S, and the second drain electrode 420D are connected to the first semiconductor layer 210 and the second semiconductor layer 400 through contact holes formed in the first gate insulating layer 120, the second insulating layer 130, the third insulating layer 140, the second gate insulating layer 150, and the fourth insulating layer 160.

The third source electrode 330S, the third drain electrode 330D, the fourth source electrode 530S, and the fourth drain electrode 530D are connected to the third semiconductor layer 310 and the fourth semiconductor layer 510 through contact holes formed in the second gate insulating layer 150 and the fourth insulating layer 160.

The first source electrode 230S, the first drain electrode 230D, the second source electrode 420S, the second drain electrode 420D, the third source electrode 330S, the third drain electrode 330D, the fourth source electrode 530S, and the fourth drain electrode 530D can be formed through the same process and can be made of one or more of silver (Ag), molybdenum (Mo), copper (Cu), titanium (Ti), aluminum (Al), chromium (Cr), gold (Au), nickel (Ni), neodymium (Nd), tungsten (W), and gold (Au).

A first planarization layer 170 can be disposed on the first source electrode 230S, the first drain electrode 230D, the second source electrode 420S, the second drain electrode 420D, the third source electrode 330S, the third drain electrode 330D, the fourth source electrode 530S, and the fourth drain electrode 530D.

The first planarization layer 170 can be formed of an organic insulating layer such as polyacrylate and polyimide, thereby reducing a step due to lines and contact holes formed thereunder.

A connection electrode 240 for connecting the first drain electrode 230D to an anode electrode 600 can be disposed on the first planarization layer 170.

The connection electrode 240 can be electrically connected to the first drain electrode 230D through a hole formed in the first planarization layer 170.

The connection electrode 240 can be made of at least one of titanium (Ti), molybdenum (Mo), copper (Cu), aluminum (Al), silver (Ag), chromium (Cr), gold (Au), neodymium (Nd), nickel (Ni), or an alloy thereof, and the embodiments of the present disclosure are not limited thereto.

A first line 630 can be disposed by being formed in the non-display area NA in the same process as the connection electrode 240.

The first line 630 can be one of lines for transmitting a voltage applied to a cathode electrode 620 as a low-potential voltage in the non-display area NA.

A second planarization layer 180 can be disposed on the connection electrode 240 and the first line 630. The second planarization layer 180 can be formed of an organic insulating layer such as polyacrylate and polyimide, and the embodiments of the present disclosure are not limited thereto.

The anode electrode 600 can be disposed on the second planarization layer 180. The anode electrode 600 can be electrically connected to the connection electrode 240 through a hole formed in the second planarization layer 180.

A second line 640 can be formed in the non-display area NA in the same process as the process of forming the anode electrode 600. The second line 640 can be disposed to overlap portions of the first gate driving transistor GT1 and the second gate driving transistor GT2 and connected to the first line 630 disposed in the non-display area NA to apply a low-potential voltage to the cathode electrode 620.

The anode electrode 600 and the second line 640 can be made of at least one of silver (Ag), aluminum (Al), gold (Au), molybdenum (Mo), tungsten (W), chromium (Cr), lead (Pd), indium tin oxide (ITO), indium zinc oxide (IZO), or an alloy thereof, and the embodiments of the present disclosure are not limited thereto.

A bank 190 can be disposed on the anode electrode 600, the second line 640, and the second planarization layer 180.

The bank 190 can separate a plurality of sub-pixels SP, thereby minimizing light bleeding and preventing color mixing occurring at any viewing angle.

The bank 190 can expose the anode electrode 600 corresponding to the light emitting area and cover an end portion of the anode electrode 600.

The bank 190 can be made of at least one of an inorganic insulating material such as silicon nitride (SiNₓ) or silicon oxide (SiOₓ), or an organic insulating material such as BCB, an acrylic resin, an epoxy resin, a phenolic resin, a polyamide resin, or a polyimide resin, but is not limited thereto.

A spacer 191 can be further disposed on the bank 190. The spacer 191 can support a gap between the substrate 100 on which the light emitting element layer 610 is formed and an upper substrate, thereby minimizing damage to elements inside the display panel when an external physical impact occurs. The spacer 191 can be made of the same material as the bank 190 and formed simultaneously with the bank 190, but is not limited thereto.

The light emitting element layer 610 can be disposed on an opening of the bank 190 that exposes the anode electrode 600. The light emitting element layer 610 can include one or more organic light emitting layers of a red light emitting layer, a green light emitting layer, a blue light emitting layer, and a white light emitting layer to emit light of a specific color. In addition, the light emitting element layer 610 can further include a hole injection layer, a hole transport layer, an electron transport layer, and an electron injection layer in addition to the organic light emitting layer, but is not limited thereto.

The hole injection layer, the hole transport layer, the electron transport layer, and the electron injection layer with different thicknesses and materials can be disposed in each sub-pixel or disposed commonly over the entire display area AA.

When the light emitting element layer 610 is disposed commonly over the entire display area AA, a color filter can be disposed above the light emitting element layer 610 to overlap the light emitting area of the sub-pixel in order to emit light corresponding to each sub-pixel.

The cathode electrode 620 can be disposed on the light emitting element layer 610. The cathode electrode 620 can supply electrons to the light emitting element layer 610 and can be made of a conductive material with a low work function.

When the display apparatus 10 is a top-emission type, the cathode electrode 620 can be disposed using a transparent conductive material that transmits light. For example, the cathode electrode 620 can be made of at least one of ITO and IZO, but is not limited thereto.

In addition, the cathode electrode 620 can be disposed using a semitransparent conductive material that transmits light. For example, the cathode electrode 620 can be made of at least one of alloys such as LiF/Al, CsF/Al, Mg:Ag, Ca/Ag, Ca:Ag, LiF/Mg:Ag, LiF/Ca/Ag, and LiF/Ca:Ag, but is not limited thereto.

When the display apparatus 10 is a bottom-emission type, the cathode electrode 620 can be disposed using an opaque conductive material as a reflective electrode that reflects light. For example, the cathode electrode 620 can be made of at least one of silver (Ag), aluminum (Al), gold (Au), molybdenum (Mo), tungsten (W), chromium (Cr), or an alloy thereof.

A plurality of driving circuit parts and a dam part NADM of the non-display area are disposed in the non-display area NA of the display apparatus 10.

The non-display area NA can be an area in which a connection part that electrically connects the cathode electrode 620 to lines through which a voltage is applied to the cathode electrode 620, and the display apparatus 10 using the dam parts of the plurality of non-display areas are sealed.

The first insulating layer 110, the first gate insulating layer 120, the second insulating layer 130, and the third insulating layer 140 of the display area AA can be disposed to extend in the non-display area NA.

The lines can be disposed in the non-display area NA so that power voltages and touch signals that are applied from the FPCB of the display apparatus 10 are connected to the display panel through the lines.

The first line 630 can be disposed on the first planarization layer 170, can be in contact with side surfaces of the first planarization layer 170, the fourth insulating layer 160, and the second gate insulating layer 150, and can be disposed to extend between a first dam DM1 and the third insulating layer 140 of the non-display area NA.

The first dam DM1 can be stacked by being made of the same material and formed in the same process as the first planarization layer 170 and the bank 190.

A second dam DM2 can be stacked by being made of the same material and formed in the same process as the first planarization layer 170, the second planarization layer 180, the bank 190, and the spacer 191.

The first dam DM1 and the second dam DM2 can have a first height and a second height, respectively, and surround the display area AA.

The second height can be formed to be higher than the first height. Even when a second encapsulation layer 720 goes beyond the first dam DM1, the second encapsulation layer 720 may not be formed outside the second dam DM2 due to the second dam DM2.

A first encapsulation layer 710 and a third encapsulation layer 730 can be disposed to extend to an outer portion beyond the second dam DM2.

The second line 640 can be disposed to extend between the first planarization layer 170 and the bank 190 of the first dam DM1 and between the second planarization layer 180 and the bank 190 of the second dam DM2.

The cathode electrode 620 can extend to an area between the first dam DM1 and the second dam DM2 and can be electrically connected to the first line 630 and the second line 640.

An encapsulation layer 700 can be disposed on the cathode electrode 620 of the display area AA, the cathode electrode 620 of the non-display area NA, and the second dam DM2.

The encapsulation layer 700 can protect the display apparatus 10 from external moisture, oxygen, or foreign substances. For example, the encapsulation layer 700 can prevent the penetration of oxygen and moisture from the outside to prevent oxidation of the light emitting material and the electrode material.

The encapsulation layer 700 can be made of a transparent material so that light emitted from the light emitting element layer 610 can be transmitted.

The encapsulation layer 700 can include the first encapsulation layer 710, the second encapsulation layer 720, and the third encapsulation layer 730 that block the penetration of moisture or oxygen, and the embodiments of the present disclosure are not limited thereto. The first encapsulation layer 710, the second encapsulation layer 720, and the third encapsulation layer 730 can have a sequentially stacked structure, and the embodiments of the present disclosure are not limited thereto.

The first encapsulation layer 710 and the third encapsulation layer 730 can be made of at least one inorganic material of silicon nitride (SiNₓ), silicon oxide (SiOₓ), or aluminum oxide (AlyOz), but are not limited thereto.

The second encapsulation layer 720 can cover foreign substances or particles that can occur during the manufacturing process. In addition, the second encapsulation layer 720 can planarize a surface of the first encapsulation layer 710.

The second encapsulation layer 720 can be made of an organic material, for example, a polymer such as silicon oxycarbon (SiOCz), epoxy, polyimide, polyethylene, or acrylate, but is not limited thereto.

A touch buffer layer 800 can be disposed on the third encapsulation layer 730. The touch buffer layer 800 can be disposed on the entire surface of the display area AA and the non-display area NA and disposed to extend to a pad part. The touch buffer layer 800 can be a first insulating layer and is not limited to the term.

The touch buffer layer 800 can be made of at least one inorganic material of silicon nitride (SiNx), silicon oxide (SiOx), or aluminum oxide (AlyOz), and is not limited thereto.

A first touch electrode 810 can be disposed on the touch buffer layer 800.

The touch operation can be driven by a plurality of detection electrodes and a plurality of driving electrodes that are disposed in the display area AA. The detection electrode includes a plurality of sub-detection electrodes Rx that extend in a first direction and are disposed at a predetermined interval in a second direction. The plurality of detection electrodes can be formed continuously without disconnection in the first direction.

The plurality of driving electrodes include a plurality of sub-driving electrodes Tx that extend in the second direction and are disposed at a predetermined interval in the first direction. The plurality of sub-driving electrodes Tx can be electrically connected in the second direction.

When the plurality of sub-detection electrodes Rx and the plurality of sub-driving electrodes Tx are formed on the same layer, the plurality of sub-driving electrodes Tx can be electrically connected by a bridge pattern.

The plurality of sub-detection electrodes Rx and the plurality of sub-driving electrodes Tx can have a metal mesh structure.

In addition, the plurality of sub-detection electrodes Rx can be electrically connected by the bridge pattern, and the plurality of sub-driving electrodes Tx can be electrically connected by being formed continuously without disconnection.

The first touch electrode 810 can electrically connect the plurality of sub-detection electrodes Rx or the plurality of sub-driving electrodes Tx.

The first touch electrode 810 can have a single-layer or multilayered structure made of a metallic material such as molybdenum (Mo), silver (Ag), titanium (Ti), copper (Cu), aluminum (Al), titanium/aluminum/titanium (Ti/Al/Ti), molybdenum/aluminum/molybdenum (Mo/Al/Mo), but is not limited thereto.

A touch insulating layer 820 can be disposed on the first touch electrode 810. The touch insulating layer 820 can be disposed on the entire surface of the display area AA and the non-display area NA and disposed to extend to the pad part. The touch insulating layer 820 can be a second insulating layer and is not limited to the term.

The touch insulating layer 820 can be made of at least one inorganic material of silicon nitride (SiNx), silicon oxide (SiOx), or aluminum oxide (AlyOz), and is not limited thereto.

A second touch electrode 830 can be disposed on the touch insulating layer 820. The second touch electrode 830 can be a plurality of sub-detection electrodes Rx or a plurality of sub-driving electrodes Tx for touch driving.

In addition, the first touch electrode 810 can be a bridge electrode for electrically connecting the second touch electrodes 830 spaced apart from each other, but is not limited thereto.

A touch line 840 for transmitting a touch driving signal to the non-display area NA can be disposed in the same process as the process of forming the second touch electrode 830.

The touch line 840 can overlap the first gate driving transistor GT1 or the second gate driving transistor GT2 and can be disposed to extend to the pad part.

The second touch electrode 830 and the touch line 840 can have a single-layer or multilayered structure made of a metallic material such as molybdenum (Mo), silver (Ag), titanium (Ti), copper (Cu), aluminum (Al), titanium/aluminum/titanium (Ti/Al/Ti), molybdenum/aluminum/molybdenum (Mo/Al/Mo), but are not limited thereto.

A third planarization layer 850 can be disposed on the second touch electrode 830 and the touch line 840.

The third planarization layer 850 can cover and planarize the second touch electrode 830, the touch line 840, and the touch insulating layer 820. In addition, the third planarization layer 850 can be made of one or more organic insulating materials such as BCB, an acrylic resin, an epoxy resin, a phenolic resin, a polyamide resin, or a polyimide resin, but is not limited thereto.

An adhesive layer 900 and a cover window 910 can be disposed on the third planarization layer 850.

Embodiments of the first area PH shown in FIG. 2 will now be described in detail with reference to FIGS. 4 to 7.

FIG. 4 shows a cross-sectional view cut along line B-B′ in FIG. 2 according to one embodiment of the present disclosure.

Referring to FIG. 4, to arrange a camera in the display area AA, the first area PH includes the hole area H, the trimming margin part TM surrounding the hole area H, the first pattern part PT1, the first dam part DM, the second pattern part PT2, and the routing line area RK.

The hole area H can be positioned in a central portion of the first area PH and formed to physically pass through from the substrate 100 to the third planarization layer 850. The hole area H can include a camera, a sensor, and a light source, and light can easily be transmitted above the camera or sensor by the hole area H.

In the routing line area RK, routing lines for electrically connecting lines connected to sub-pixels of the display area AA through the first area PH are disposed.

A first routing line 20 can be formed in the same process as the process of forming the first gate electrode 220, the second gate electrode 410, and the first capacitor electrode Cst1 on the first gate insulating layer 120 disposed to extend to the first area PH, and the embodiments of the present disclosure are not limited thereto.

A second routing line 30 can be formed in the same process as the process of forming the second capacitor electrode Cst2 on the second insulating layer 130 disposed to extend to the first area PH, and the embodiments of the present disclosure are not limited thereto.

A third routing line 40 can be formed in the same process as the first source electrode 230S, the first drain electrode 230D, the second source electrode 420S, the second drain electrode 420D, the third source electrode 330S, the third drain electrode 330D, the fourth source electrode 530S, and the fourth drain electrode 530D on the fourth insulating layer 160 disposed to extend to the first area PH, and the embodiments of the present disclosure are not limited thereto.

A fourth routing line 50 can be formed in the same process as the connection electrode 240 on the first planarization layer 170 disposed to extend to the first area PH, and the embodiments of the present disclosure are not limited thereto.

The first routing line 20, the second routing line 30, the third routing line 40, and the fourth routing line 50 can be electrically connected and disposed to overlap at least partially in the routing line area RK, but are not limited thereto.

In the routing line area RK, the first touch line 811 and the second touch line 831 formed in the same process as the first touch electrode 810 and the second touch electrode 830 can be formed to electrically connect the touch driving signal of the display area AA and transmit the touch driving signal to another area of the display area AA through the first area PH.

Gate lines of the sub-pixels of the display area AA can be connected to the first routing line 20 and the second routing line 30 and can also be electrically connected in the first area PH, and data lines of the sub-pixels can be connected to the third routing line 40 and the fourth routing line 50 and can also be electrically connected in the first area PH.

The first pattern part PT1 and the second pattern part PT2 are disposed to surround the hole area H. The first pattern part PT1 and the second pattern part PT2 can include a plurality of patterns PT, and each of the plurality of patterns PT can be formed of a lower pattern PTa and an upper pattern PTb. The lower pattern PTa can be simultaneously made of the same material as the fourth insulating layer 160. The upper pattern PTb can be simultaneously made of the same material as the second planarization layer 180. However, the material and number of layers of insulating layers of the plurality of patterns PT are not limited thereto.

In addition, the plurality of patterns PT can be disposed to be spaced a predetermined distance from each other.

The plurality of patterns PT can prevent moisture from penetrating the display area AA through the light emitting element layer 610 that is vulnerable to moisture penetration.

A width of a lower surface of the upper pattern PTb disposed above the lower pattern PTa is larger than a width of an upper surface of the lower pattern PTa.

The light emitting element layer 610 disposed on an upper surface and side surfaces of the upper pattern PTb is not formed on side surfaces of the lower pattern PTa due to a separation space between the lower surface of the upper pattern PTb and the side surfaces of the lower pattern PTa and thus can be disconnected by the plurality of patterns PT.

In addition, since the first encapsulation layer 710 disposed in the routing line area RK, the first pattern part PT1, the first dam part DM, and the second pattern part PT2 of the first area PH can be formed on the upper surface and side surfaces of the upper pattern PTb and a portion of the lower surface of the upper pattern PTb and is not formed on portions of the side surfaces of the lower pattern PTa, an empty space ES can be formed.

The first dam part DM between the first pattern part PT1 and the second pattern part PT2 can include an align mark LT MARK. The align mark LT MARK serves as a laser trimming align mark, allowing the position to be identified when forming a hole H by laser trimming, enabling penetration of the substrate and the remaining insulating layers.

In one example, the align mark LT MARK can be formed through the same process as the first routing line 20. Accordingly, the align mark LT MARK can be formed of the same material and on the same layer as the first routing line 20. For instance, the align mark LT MARK can be positioned on the first gate insulating layer 120.

A hole dam HDM can be disposed in the first dam part DM between the first pattern part PT1 and the second pattern part PT2. The hole dam HDM can be positioned over the align mark LT MARK. Thus, hole dam HDM can be arranged to overlap with the align mark LT MARK in the vertical direction.

The hole dam HDM can prevent the second encapsulation layer 720 from overflowing into the hole area H. One or more hole dams HDM can be disposed continuously and disposed in the first pattern part PT1 and the second pattern part PT2.

The hole dam HDM can be formed by stacking a first dam layer DA1, a second dam layer DA2, a third dam layer DA3, and a fourth dam layer DA4 that are formed in the same process and the same material as the fourth insulating layer 160, the second planarization layer 180, the bank 190, and the spacer 191, and the embodiments of the present disclosure are not limited thereto.

Due to the hole dam HDM, the second encapsulation layer 720 can be disposed on the second pattern part PT2 and a portion of the hole dam HDM.

The third encapsulation layer 730 can be disposed to extend to the routing line area RK, the first pattern part PT1, the first dam part DM, and the second pattern part PT2 of the first area PH and can be in contact with the first encapsulation layer 710 on the upper surfaces or side surfaces of the plurality of patterns PT of the first pattern part PT1.

The touch buffer layer 800 can be disposed to extend to the routing line area RK, the first pattern part PT1, the hole dam part HDM, and the second pattern part PT2 of the first area PH and can be in contact with the third encapsulation layer 730.

The touch insulating layer 820 can be disposed to extend to the routing line area RK, the first pattern part PT1, the hole dam part HDM, and the second pattern part PT2 of the first area PH and can be disposed in contact with an upper surface of the touch buffer layer 800 on the first pattern part PT1, the second pattern part PT2, and the hole dam part HDM.

A hole crack detection line 832 can be disposed on the touch insulating layer 820 in an area overlapping the second pattern part PT2. The hole crack detection line 832 can detect hole formation and an external impact through a change in resistance value of the hole crack detection line 832.

The hole crack detection line 832 can be formed to surround the hole area H in the area of the second pattern part PT2 and can extend to the non-display area NA of the display apparatus 10 to be connected to the pad part.

The first encapsulation layer 710, the third encapsulation layer 730, the touch buffer layer 800, and the touch insulating layer 820 can be disposed on the first pattern part PT1, the hole dam part HDM, and the second pattern part PT2, thereby preventing damage to the plurality of patterns PT due to an external impact caused by forming the hole area H in the display area AA and maintaining the moisture penetration prevention effect due to the structure of the plurality of patterns PT.

The trimming margin part TM can be disposed between the hole area H and the first pattern part PT1 of the first area PH. To prevent damage and crack propagation by the laser when removing the substrate 100 and the plurality of layers in the laser trimming process for forming the hole area H, the trimming margin part TM with a predetermined distance can be disposed.

The end portions of the first gate insulating layer 120, the second insulating layer 130, the third insulating layer 140, the second gate insulating layer 150, and the fourth insulating layer 160 that are made of an inorganic insulating material can be disposed between the first pattern part PT1 and the trimming margin part TM.

The end portions of the first gate insulating layer 120, the second insulating layer 130, the third insulating layer 140, the second gate insulating layer 150, and the fourth insulating layer 160 can be formed to have a step in a step-like structure.

A cover layer 900 can be disposed to cover the end portions of the first gate insulating layer 120, the second insulating layer 130, the third insulating layer 140, the second gate insulating layer 150, and the fourth insulating layer 160.

The cover layer 900 can be disposed to extend to the first pattern part PT1 and the trimming margin part TM and can be formed of a first layer 901 and a second layer 902, and the first layer 901 can be made of the same material as the second planarization layer 180 and the second layer 902 can be made of the same material and formed in the same process as the bank 190.

In addition, a third layer 903 can be disposed on the second layer 902 using the same material and the same process as the spacer 191, but is not limited thereto.

The organic light emitting layer 610 can be disposed to extend to the trimming margin part TM along an upper surface of the cover layer 900.

When an external force is applied to a layer made of an inorganic insulating material, cracks can easily propagate to nearby areas. It is possible to prevent crack propagation by not forming the first gate insulating layer 120, the second insulating layer 130, the third insulating layer 140, the second gate insulating layer 150, and the fourth insulating layer 160 that are made of an inorganic insulating material in the trimming margin part TM and covering and protecting the end portions with the cover layer 900.

The first encapsulation layer 710, the third encapsulation layer 730, the touch buffer layer 800, and the touch insulating layer 820 can be disposed to extend to an upper portion of the cover layer 900 disposed in the first pattern part PT1.

The ends of the first encapsulation layer 710, the third encapsulation layer 730, the touch buffer layer 800, and the touch insulating layer 820 can be formed to have a step in a step-like structure.

At least a portion of the trimming margin part TM can be formed so that the third planarization layer 850 can be in direct contact with the substrate 100 by removing all layers on the substrate 100.

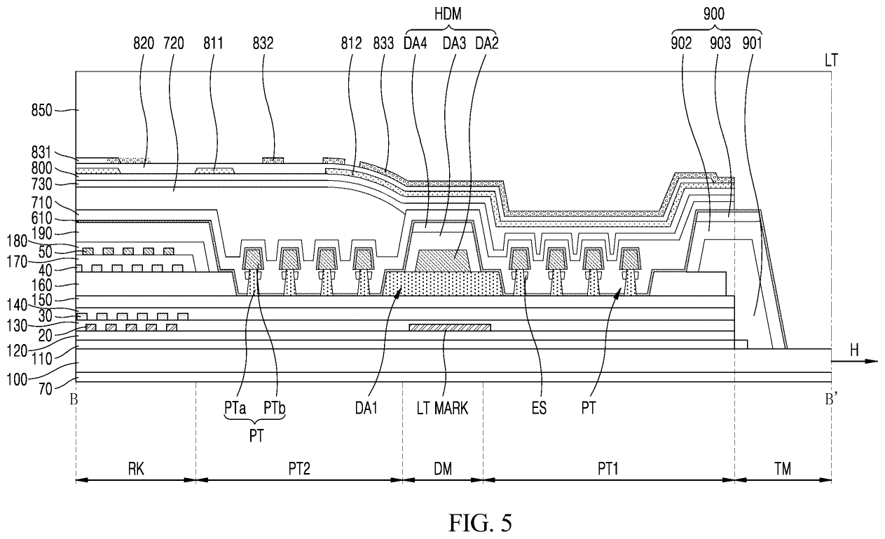

FIG. 5 shows a cross-sectional view cut along line B-B′ in FIG. 2 according to another embodiment of the present disclosure. In describing the components of FIG. 5, descriptions of components which are the same as or correspond to those of FIG. 4 will be omitted or simplified.

Referring to FIG. 5, a first touch metal layer 812 and a second touch metal layer 833 can be disposed in an area overlapping the first pattern part PT1, the hole dam part HDM, and the second pattern part PT2.

The first touch metal layer 812 can be made of the same material and formed in the same process as the first touch line 811, and the second touch metal layer 833 can be made of the same material and formed in the same process as the second touch line 831 and the hole crack detection line 832.

The first touch metal layer 812 and the second touch metal layer 833 can cover the patterns PT of the first pattern part PT1 and the second pattern part PT2 to prevent external impact transmission from the top and can be connected to a low-potential voltage line to be connected to a ground line of the display apparatus 10.

Due to the step between the touch insulating layer 820 and the touch buffer layer 800 on the cover layer 900, the first touch metal layer 812 and the second touch metal layer 833 can be connected, but are not limited thereto.

In addition, the first touch metal layer 812 and the second touch metal layer 833 that are made of a metallic material can prevent moisture penetrating from the outside from being transmitted to the first pattern part PT1, the hole dam part HDM, and the second pattern part PT2, thereby securing the moisture penetration reliability characteristic.

A portion of the first touch metal layer 812 can be disposed to overlap the upper portion of the cover layer 900 in the area of the first pattern part PT1.

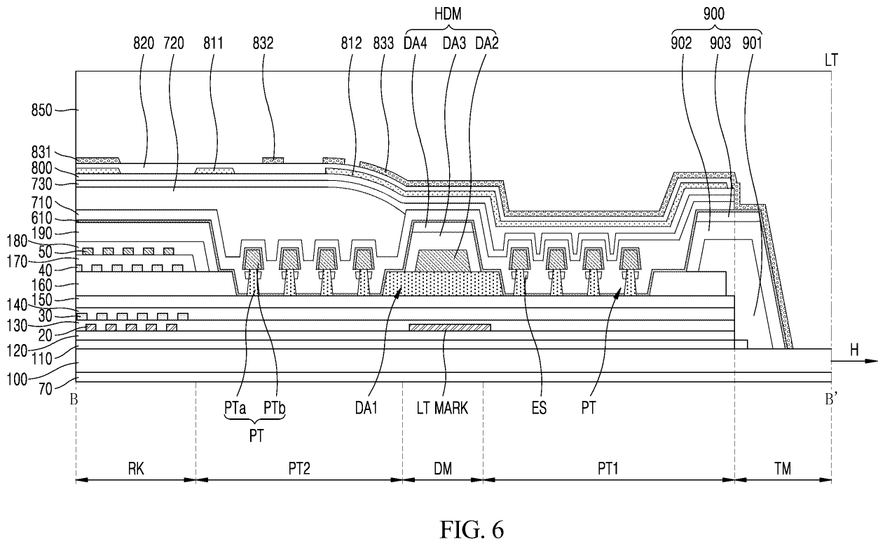

FIG. 6 shows a cross-sectional view cut along line B-B′ in FIG. 2 according to another embodiment of the present disclosure. In describing components of FIG. 6, descriptions of components which are the same as or correspond to those of FIGS. 4 and 5 will be omitted or simplified.

Referring to FIG. 6, the second touch metal layer 833 can be disposed to extend along the upper portion and side surfaces of the cover layer 900 to cover the cover layer 900. It is possible to prevent the penetration of external moisture by covering the side surfaces of the cover layer 900.

In addition, the first touch metal layer 812 can also extend along the upper portion and side surfaces of the cover layer 900 together with the second touch metal layer 833, but is not limited thereto.

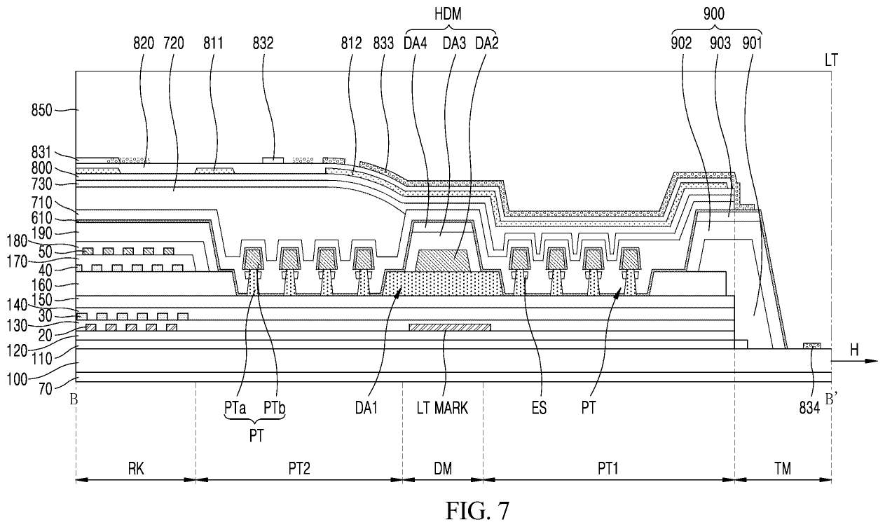

FIG. 7 shows a cross-sectional view cut along line B-B′ in FIG. 2 according to another embodiment of the present disclosure. In describing components of FIG. 7, descriptions of components which are the same as or correspond to those of FIGS. 4 to 6 will be omitted or simplified.

Referring to FIG. 7, a crack prevention line 834 can be disposed in the trimming margin part TM. The crack prevention line 834 can be made of the same material and formed in the same process as the second touch metal layer 833 and the hole crack detection line 832.

It is possible to prevent cracks occurring in the hole area H due to an external impact from propagating toward the first pattern part PT1 and the display area AA by arranging the crack prevention line 834.

The crack prevention line 834 can be disposed in one or more trimming margin parts TM, but is not limited thereto.

A support plate 70 of the display apparatus 10 can be disposed under the substrate 100, a hole can be formed in the support plate 70 corresponding to the hole area H to correspond to the hole area H, and a camera, a sensor, a light source, etc. can be disposed in the corresponding hole.

The support plate 70 can include a plurality of metal layers, an insulating layer, and an adhesive layer, but is not limited thereto.

A display apparatus according to an embodiment of the present disclosure can be described as follows.

A display apparatus according to an embodiment of the present disclosure includes a substrate including a display area and a non-display area surrounding the display area, a plurality of pixels and a first area that are disposed in the display area, each of the plurality of pixels including a plurality of transistors, a first planarization layer disposed on the plurality of transistors, and a connection electrode and a second planarization layer on the first planarization layer, wherein the first area includes a hole area, a first pattern part, and a first dam part, end portions of a plurality of insulating layers disposed between the hole area and the first pattern part, and a cover layer covering the end portions of the plurality of insulating layers.

According to some embodiments of the present disclosure, the plurality of transistors can include a gate electrode, a semiconductor layer, a source electrode, and a drain electrode.

According to some embodiments of the present disclosure, a gate insulating layer disposed between the gate electrode and the semiconductor layer, and an interlayer insulating layer disposed between the semiconductor layer and the source and drain electrodes can be further included.

According to some embodiments of the present disclosure, a pixel electrode and a bank can be disposed on the first planarization layer, a light emitting layer and a second electrode can be disposed on the pixel electrode, and an encapsulation layer disposed on the second electrode can be further disposed.

According to some embodiments of the present disclosure, the plurality of insulating layers can be formed of a gate insulating layer and an interlayer insulating layer, and the end portions of the plurality of insulating layers can have a step.

According to some embodiments of the present disclosure, a cover layer can be formed of a first layer and a second layer, and the first layer can be made of the same material as the second planarization layer, and the second layer can be made of the same material as the bank.

According to some embodiments of the present disclosure, the encapsulation layer can include a first encapsulation layer, a second encapsulation layer, and a third encapsulation layer, and the first encapsulation layer or the third encapsulation layer can be disposed on a portion of the cover layer.

According to some embodiments of the present disclosure, a touch insulating layer, a first touch metal layer, and a second touch metal layer can be disposed on the encapsulation layer.

According to some embodiments of the present disclosure, the touch insulating layer, the first touch metal layer, and the second touch metal layer can be disposed to overlap each other on the first pattern part, and the first touch metal layer and the second touch metal layer can be disposed to extend on an upper surface of the cover layer.

According to some embodiments of the present disclosure, the first touch metal layer and the second touch metal layer can be in contact with each other on the upper surface of the cover layer, and the first touch metal layer or the second touch metal layer can cover one side surface of the cover layer and can be disposed to extend to a trimming margin part between the first pattern part and the hole area.

According to some embodiments of the present disclosure, a crack prevention line can be disposed in the trimming margin part between the first pattern part and the hole area, and the crack prevention line can be made of the same material as the second touch metal layer.

A display apparatus according to an embodiment of the present disclosure includes a substrate including a display area, a plurality of insulating layers on the substrate, a first area disposed in the display area and including a hole area, a trimming margin part, and a pattern part, and a cover layer covering side surfaces of the plurality of insulating layers exposed along the trimming margin part.

According to some embodiments of the present disclosure, the cover layer can be formed of at least one organic layer.

According to some embodiments of the present disclosure, the cover layer can be disposed on at least portions of the pattern part and the trimming margin part.

According to some embodiments of the present disclosure, the display apparatus can further include a metal layer overlapping the pattern part, and the metal layer can be disposed to extend to an upper portion of the cover layer.

According to some embodiments of the present disclosure, an organic light emitting layer can be disposed on the cover layer, and the organic light emitting layer can extend along one side surface of the cover layer.

According to some embodiments of the present disclosure, an inorganic insulating layer can be disposed on at least a portion of the cover layer, and an end of the inorganic insulating layer can have a stepped portion.

According to some embodiments of the present disclosure, a protective layer can be disposed on entire surface of the display area excluding the hole area.

Although the embodiments of the present disclosure have been described above in more detail with reference to the accompanying drawings, the present disclosure is not necessarily limited to these embodiments, and various modifications can be carried out without departing from the technical spirit of the present disclosure. Therefore, the embodiments disclosed in the present disclosure are not intended to limit the technical spirit of the present disclosure, but is intended to describe the same, and the scope of the technical spirit of the present disclosure is not limited by these embodiments. Therefore, it should be understood that the above-described embodiments are illustrative and not restrictive in all aspects.

What is claimed is:

1. A display apparatus comprising:
a substrate including a display area and a non-display area adjacent to the display area, the display area including a first area;
a plurality of pixels disposed in the display area, each of the plurality of pixels including a plurality of transistors;
a first planarization layer disposed on the plurality of transistors; and
a connection electrode and a second planarization layer disposed on the first planarization layer,
wherein the first area of the display area includes:
a hole area, a first pattern part, and a first dam part;
a plurality of insulating layers having end portions disposed between the hole area and the first pattern part; and
a cover layer covering the end portions of the plurality of insulating layers.

2. The display apparatus of claim 1, wherein the plurality of transistors include a gate electrode, a semiconductor layer, and source and drain electrodes.

3. The display apparatus of claim 2, wherein the plurality of insulating layers include:
a gate insulating layer disposed between the gate electrode and the semiconductor layer; and
an interlayer insulating layer disposed between the semiconductor layer and the source and drain electrodes.

4. The display apparatus of claim 3, further comprising:
a pixel electrode and a bank that are disposed on the first planarization layer;
a light emitting layer and a second electrode that are disposed on the pixel electrode; and
an encapsulation layer disposed on the second electrode.

5. The display apparatus of claim 4, wherein the end portions of the plurality of insulating layers have a step.

6. The display apparatus of claim 4, wherein the cover layer includes a first layer and a second layer, and
wherein the first layer is made of a same material as the second planarization layer, and the second layer is made of a same material as the bank.

7. The display apparatus of claim 4, wherein the encapsulation layer includes a first encapsulation layer, a second encapsulation layer, and a third encapsulation layer, and
wherein the first encapsulation layer or the third encapsulation layer is disposed on a portion of the cover layer.

8. The display apparatus of claim 4, further comprising a touch insulating layer, a first touch metal layer, and a second touch metal layer that are disposed on the encapsulation layer.

9. The display apparatus of claim 8, wherein the touch insulating layer, the first touch metal layer, and the second touch metal layer are disposed to overlap each other on the first pattern part, and
wherein the first touch metal layer and the second touch metal layer are disposed to extend on an upper surface of the cover layer.

10. The display apparatus of claim 9, wherein the first touch metal layer and the second touch metal layer are in contact with each other on the upper surface of the cover layer, and
wherein the first touch metal layer or the second touch metal layer covers one side surface of the cover layer and is disposed to extend to a trimming margin part between the first pattern part and the hole area.

11. The display apparatus of claim 9, further comprising a crack prevention line disposed in the trimming margin part between the first pattern part and the hole area,
wherein the crack prevention line is made of a same material as the second touch metal layer.

12. A display apparatus comprising:
a substrate including a display area;
a plurality of insulating layers on the substrate;
a first area disposed in the display area and including a hole area, a trimming margin part, and a pattern part; and
a cover layer covering side surfaces of the plurality of insulating layers exposed along the trimming margin part.

13. The display apparatus of claim 12, wherein the cover layer includes at least one organic layer.

14. The display apparatus of claim 12, wherein the cover layer is disposed in at least portions of the pattern part and the trimming margin part.

15. The display apparatus of claim 12, further comprising a metal layer overlapping the pattern part,
wherein the metal layer is disposed to extend to an upper portion of the cover layer.

16. The display apparatus of claim 12, further comprising an organic light emitting layer disposed on the cover layer,
wherein the organic light emitting layer extends along one side surface of the cover layer.

17. The display apparatus of claim 16, further comprising an inorganic insulating layer disposed on at least a portion of the cover layer,
wherein an end of the inorganic insulating layer has a step.

18. The display apparatus of claim 12, further comprising a protective layer disposed on an entire surface of the display area excluding the hole area.
